(19) United States
(12) Patent Application Publication
(10) Pub. No.: US 2023/0238414 A1
(43) Pub. Date: Jul. 27, 2023

(54) PHOTODETECTOR AND CAMERA SYSTEM

(71) Applicant: SONY SEMICONDUCTOR SOLUTIONS CORPORATION, KANAGAWA (JP)

(72) Inventor: ATSUSHI TODA, KANAGAWA (JP)

(21) Appl. No.: 18/005,030

(22) PCT Filed: Jun. 17, 2021
(86) PCT No.: PCT/JP2021/023071

§ 371 Date: Jan. 10, 2023

(30) Foreign Application Priority Data
Jul. 20, 2020 (JP) 2020-124037

(51) Int. Cl. H01L 27/146; G01S 17/89

(52) U.S. Cl. CPC H01L 27/14627; H01L 27/14649; G01S 17/89; G01S 17/08

(57) ABSTRACT

A photodetector including: a semiconductor substrate including therein a photoelectric conversion section; a scattering structure provided cyclically on the semiconductor substrate on a side of an incident surface of light; and a prism-shaped on-chip lens provided further on the scattering structure on a side of an incident surface of the light, and having a planar incident surface of the light.

### TECHNICAL FIELD

The present disclosure relates to a photodetector and a camera system.

### BACKGROUND ART

In recent years, it has been proposed, in a photodetector such as a CMOS (Complementary Metal-Oxide-Semiconductor) image sensor or a CCD (Charge Coupled Device) image sensor, that a length of an optical path of incident light be increased in a photoelectric conversion section to thereby improve detection sensitivity for the incident light.

For example, it has been proposed to provide an uneven structure on a light-receiving surface of a pixel of the photodetector and scatter incident light to thereby further increase a length of an optical path of the incident light in a photoelectric conversion section (e.g., PTL 1).

### CITATION LIST

### Patent Literature

PTL 1: Japanese Unexamined Patent Application Publication No. 2019-46960

### SUMMARY OF THE INVENTION

Such a photodetector is desired to have further improved detection sensitivity for incident light. In particular, long-wavelength incident light results in having lowered light absorption efficiency per unit thickness of a photoelectric conversion section due to wavelength dependency of light absorption coefficient. It is therefore important, in the photodetector, to cause the photoelectric conversion section to absorb the long-wavelength incident light more efficiently.

It is desirable to provide a photodetector and a camera system having further improved light absorption efficiency.

A photodetector according to an embodiment of the present disclosure includes: a semiconductor substrate including therein a photoelectric conversion section; a scattering structure provided cyclically on the semiconductor substrate on a side of an incident surface of light; and a prism-shaped on-chip lens provided further on the scattering structure on a side of an incident surface of the light, and having a planar incident surface of the light.

A camera system according to an embodiment of the present disclosure includes a photodetector, in which the photodetector includes a semiconductor substrate including therein a photoelectric conversion section, a scattering structure provided cyclically on the semiconductor substrate on a side of an incident surface of light, and a prism-shaped on-chip lens provided further on the scattering structure on a side of an incident surface of the light, and having a planar incident surface of the light.

In the photodetector and the camera system according to an embodiment of the present disclosure, there are provided: the scattering structure having a cyclic structure, on the semiconductor substrate including therein the photoelectric conversion section, on the side of the incident surface of the light; and the prism-shaped on-chip lens having a planar incident surface of the light. This enables, for example, the photodetector to cause the prism-shaped on-chip lens to further increase the maximum incident angle of incident light entering the scattering structure, thus making it possible for the scattering structure to generate diffraction of the incident light more strongly.

### BRIEF DESCRIPTION OF THE DRAWINGS

FIG. 1 is a longitudinal cross-sectional view of a cross-sectional configuration of a photodetector according to an embodiment of the present disclosure.

FIG. 2A is a top view of a planar configuration of a scattering structure in FIG. 1.

FIG. 2B is a top view of a planar configuration of an on-chip lens in FIG. 1.

FIG. 3 is an explanatory diagram that describes principles of light condensing by the on-chip lens.

FIG. 4 is an explanatory diagram that describes a condition of diffraction by the scattering structure.

FIG. 5A is a heat map diagram estimating a power distribution of a wave front of incident light in a photodetector including a spherical-shaped on-chip lens.

FIG. 5B is a heat map diagram estimating a power distribution of a wave front of incident light in a photodetector including a prism-shaped on-chip lens.

FIG. 6A is a graph diagram estimating quantum efficiency of a photodetector including a spherical-shaped or prism-shaped on-chip lens and including a scattering structure.

FIG. 6B is a graph diagram estimating quantum efficiency of a photodetector including a spherical-shaped or prism-shaped on-chip lens but not including a scattering structure.

FIG. 7 is a top view of a variation of a planar configuration of a prism-shaped on-chip lens.

FIG. 8 is a graph diagram estimating quantum efficiency of a photodetector including a quadrangular-prism-shaped or octagonal-prism-shaped on-chip lens.

FIG. 9 is a plan view of an example of a mask to be used for patterning of the quadrangular-prism-shaped on-chip lens.

FIG. 10 is a longitudinal cross-sectional view of a cross-sectional configuration of a photodetector according to a first modification example.

FIG. 11 is a top view of a planar configuration of a scattering structure in FIG. 10.

FIG. 12 is a longitudinal cross-sectional view of a cross-sectional configuration of a photodetector according to a second modification example.

FIG. 13 is a graph diagram illustrating an example of a light transmittance spectrum of an infrared filter.

FIG. 14 is an explanatory diagram illustrating an overview of a camera system including the photodetector according to an embodiment of the present disclosure.

### MODES FOR CARRYING OUT THE INVENTION

The following describes embodiments of the present disclosure in detail with reference to the drawings. The embodiments described below are specific examples of the present disclosure. The technology according to the present disclosure should not be limited to the following modes. In addition, the disposition, dimensions, dimensional ratios, and the like of the respective components according to the present disclosure are not limited to the modes illustrated in the drawings.

It is to be noted that the description is given in the following order.
1. Configuration Example
2. Workings and Effects
3. Modification Examples
   3.1. First Modification Example
   3.2. Second Modification Example
4. Application Example

### 1. CONFIGURATION EXAMPLE

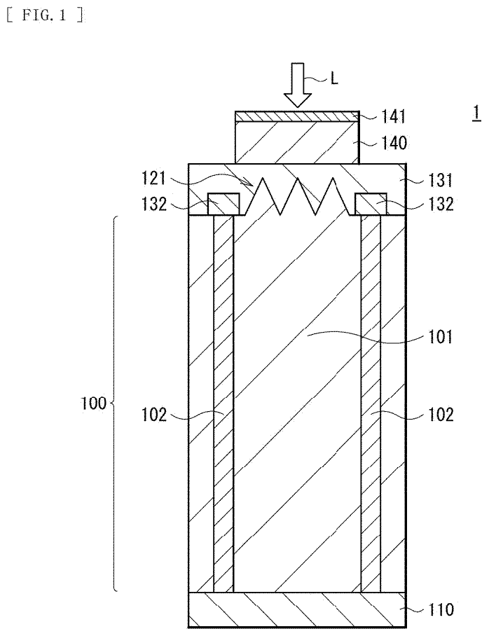

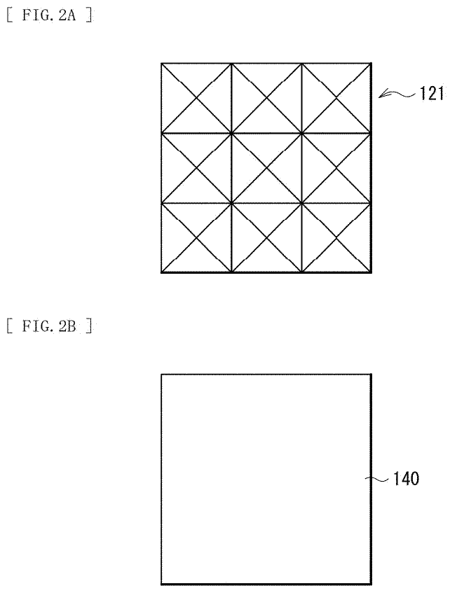

First, description is given, with reference to FIGS. 1 to 2B, of a configuration example of a photodetector 1 according to an embodiment of the present disclosure. FIG. 1 is a longitudinal cross-sectional view of a cross-sectional configuration of the photodetector 1 according to the present embodiment.

As illustrated in FIG. 1, the photodetector 1 includes, for example, a wiring layer 110, a semiconductor substrate 100 including a photoelectric conversion section 101 and an element separation section 102, a scattering structure 121, a light-blocking film 132, a planarizing film 131, an on-chip lens 140, and an antireflection film 141.

The semiconductor substrate 100 is, for example, a silicone (Si) substrate. The semiconductor substrate 100 includes the element separation section 102 extending in a thickness direction of the semiconductor substrate 100 and the photoelectric conversion section 101 provided for each pixel in a plane of the semiconductor substrate 100.

The photoelectric conversion section 101 is, for example, a photodiode that photoelectrically converts incident light L entering the photodetector 1. The photoelectric conversion section 101 is configured by an n-type impurity region provided in the semiconductor substrate 100 and a p-type impurity region provided for each semiconductor substrate 100 to allow the n-type impurity region to be interposed in the thickness direction of the semiconductor substrate 100.

The element separation section 102 includes an insulating material, and electrically separates the photoelectric conversion section 101 for each pixel. Specifically, the element separation section 102 may be configured by an insulating material that fills a groove structure dug in the thickness direction of the semiconductor substrate 100. For example, the element separation section 102 may include an insulating material (e.g., SiO₂, etc.) having a lower refractive index than that of the semiconductor substrate 100. In such a case, the element separation section 102 reflects diffracted light from the photoelectric conversion section 101 toward the element separation section 102, thereby making it possible to improve sensitivity of the photoelectric conversion section 101.

Alternatively, the element separation section 102 may be configured by an insulating material that covers the inner surface of the groove structure dug in the thickness direction of the semiconductor substrate 100 and a metal material filling the groove structure from above the insulating material. The metal material is, for example, tungsten (W), aluminum (Al), copper (Cu), a metal alloy thereof, or the like having high performance of blocking diffracted light from the photoelectric conversion section 101 toward the element separation section 102. This allows the element separation section 102 to block diffracted light from the photoelectric conversion section 101 toward the element separation section 102, thus enabling suppression of optical color mixture between pixels. This makes it possible to improve resolution of the photodetector 1.

The wiring layer 110 includes a wiring line or a circuit that converts electric charge generated by the photoelectric conversion section 101 into a pixel signal, and is provided on a surface (i.e., a front surface), of the semiconductor substrate 100, on a side opposite to a light incident surface. Specifically, the wiring layer 110 may be provided in a multilayer wiring structure of a wiring line including an electrically-conductive material provided in a plurality of layers and an insulating layer including an insulating material to cover the wiring line.

This allows for extraction of the electric charge generated in the photoelectric conversion section 101 using a transfer transistor (unillustrated) provided on the surface, of the semiconductor substrate 100, on the side opposite to the light incident surface, from the photoelectric conversion section 101. The electric charge extracted from the photoelectric conversion section 101 is converted into a pixel signal by an amplifier transistor (unillustrated) provided in the wiring layer 110 covering the transfer transistor, for example.

The scattering structure 121 is a structure provided cyclically on the semiconductor substrate 100 on a side of the light incident surface, and scatters or diffracts the incident light L on the photodetector 1. Specifically, the scattering structure 121 may be a cyclic uneven structure formed on a surface (i.e., a back surface), of the semiconductor substrate 100, on the side of the light incident surface.

Description is given of a specific structure of the scattering structure 121 with reference to FIG. 2A. FIG. 2A is a top view of a planar configuration of the scattering structure 121 in FIG. 1.

As illustrated in FIGS. 1 and 2A, the scattering structure 121 may be provided as an uneven structure in which a quadrangular-pyramid-shaped or truncated-quadrangular-pyramid-shaped recesses (i.e., inverted-pyramid-shaped recesses) are arranged cyclically in each of two-dimensional directions in the plane of the semiconductor substrate 100. For example, in a case where the pixel has a square shape of 1.5 μm on each side, the recesses of the scattering structure 121 may be provided in a cycle of 400 nm. This allows the scattering structure 121 to be provided as nine quadrangular-pyramid-shaped recesses in total arranged in a matrix of three rows and three columns within the pixel.

Such a scattering structure 121 including the quadrangular-pyramid-shaped recesses can be formed by utilizing a crystal plane of a silicon substrate, for example. Specifically, in a case where the silicon substrate is wet-etched to dig a (100) surface of Si, an opening formed in the silicon substrate forms an energetically stable (7×7) structure (so-called DAS model) by surface reconstruction, thus exposing a (111) surface of Si. Accordingly, by wet-etching the (100) plane of the silicon substrate using, as a mask, a resist pattern with cyclic openings being formed by lithography, it is possible to form the recess having a quadrangular pyramid shape, with the (111) plane of Si as a side surface.

However, the scattering structure 121 is not limited to the uneven structure in the shape exemplified above. The scattering structure 121 may be an uneven structure in which substantially cylindrical pillars or holes are arranged cyclically.

The planarizing film 131 is configured by a transparent organic resin or the like, and is provided on the semiconductor substrate 100 on the side of the light incident surface, with the scattering structure 121 being embedded therein. The planarizing film 131 may be configured by, for example, a styrene-based resin, an acrylic-based resin, a styrene-acrylic copolymer-based resin, a siloxane-based resin, or the like.

The light-blocking film 132 is configured by a light-blocking material, and is provided on the semiconductor substrate 100 on the side of the light incident surface in a manner corresponding to the element separation section 102. The light-blocking film 132 is provided at the boundary between pixels to block incident light incident across the pixels, thereby making it possible to suppress the optical color mixture between the pixels. The light-blocking film 132 may be configured by, for example, tungsten (W), aluminum (Al), copper (Cu), a metal alloy thereof, or the like.

The on-chip lens 140 is configured to have a prismatic shape with a planar light incident surface, and is provided on a surface, of the planarizing film 131, on a side of an incident surface. Specifically, the on-chip lens 140 may be configured by a transparent material to have the prismatic shape extending in a direction perpendicular to the surface, of the semiconductor substrate 100, on a light incident side.

Although described later in detail, the on-chip lens 140, which is provided to have a prismatic shape in the size of the same order as a wavelength of the incident light L, is able to condense the incident light L by utilizing the fact that a speed of light passing through the inside of the on-chip lens 140 is lower than a speed of light passing through the air. In addition, the on-chip lens 140 is able to increase a phase difference between the light passing through the inside of the on-chip lens 140 and the light passing through the air by increasing the height of the prismatic shape, and thus is able to bend the incident light L more strongly.

The photodetector 1 according to the present embodiment is able to increase an incident angle of the incident light L on the photoelectric conversion section 101 by bending the incident light L more strongly in the prism-shaped on-chip lens 140. This enables the photodetector 1 according to the present embodiment to more easily satisfy a condition of diffraction by the scattering structure 121 even for the long-wavelength incident light L. Thus, the photodetector 1 according to the embodiment is able to further increase the length of an optical path of the incident light in the photoelectric conversion section 101 by means of diffraction, thus making it possible to further enhance light absorption efficiency.

Description is given of a more specific structure of the on-chip lens 140 with reference to FIG. 2B. FIG. 2B is a top view of a planar configuration of the on-chip lens 140 in FIG. 1.

As illustrated in FIG. 2B, the on-chip lens 140 may be provided in a quadrangular prism shape having a quadrangular bottom surface using a transparent material such as Si₃N₄. For example, in a case where the pixel has a square shape of 1.5 μm on each side, the on-chip lens 140 may be provided in a quadrangular prism shape having a square bottom surface of 1.3 μm on each side

The antireflection film 141 is provided on a surface, of the on-chip lens 140, on the side of a light incident surface. The antireflection film 141 may be configured by, for example, a film having a thickness of 1/(4×n) of a wavelength λ of incident light (where n is a refractive index of a material configuring the antireflection film 141), or a multilayer dielectric film in which dielectric materials of different refractive indexes are alternately stacked on each other, etc.

### 2. WORKINGS AND EFFECTS

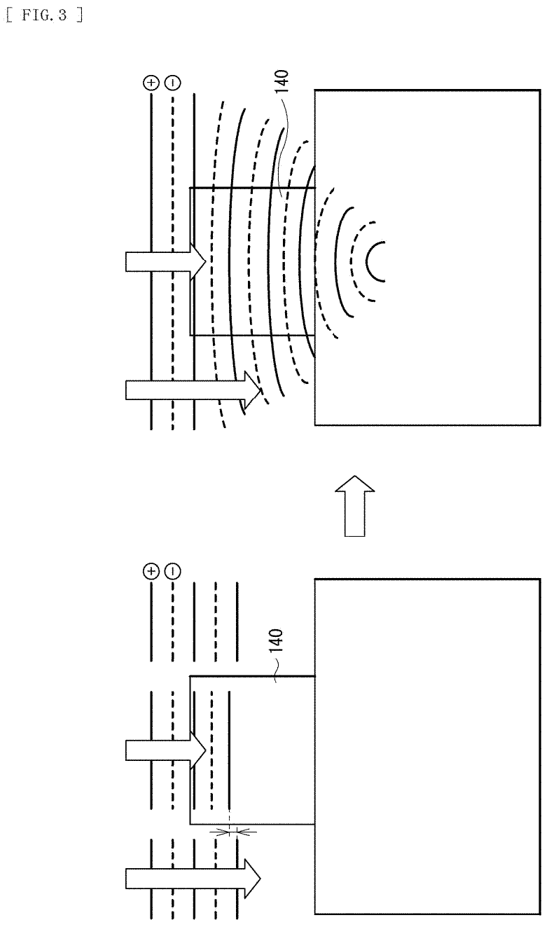

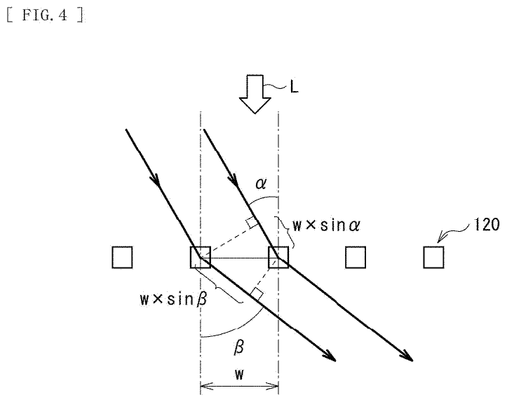

Next, description is given, with reference to FIGS. 3 to 9, of workings and effects of the photodetector 1 according to the present embodiment.

First, specific description is given, with reference to FIG. 3, of light condensing by the prism-shaped on-chip lens 140. FIG. 3 is an explanatory diagram that describes principles of the light condensing by the on-chip lens 140.

As illustrated in FIG. 3, light entering the on-chip lens 140 travels by sequentially repeating a wave front of +plane and −plane which are each an equiphase plane. Here, a speed C of light traveling in a medium can be represented as C=C₀/n by using light speed C₀ in vacuo and a refractive index n of the medium. Thus, the speed of light traveling in the on-chip lens 140 having a refractive index greater than one is slower than the speed of light traveling in the air (a refractive index of about one), thus causing the light traveling in the on-chip lens 140 to generate a phase difference with respect to the light traveling in the air. Here, in a case where the magnitude of the on-chip lens 140 nears the order of the wavelength of incident light, each wave front of the incident light becomes continuous, thus allowing the wave front of the incident light to have a curved shape toward the center of the on-chip lens 140. This enables the on-chip lens 140 to condense the incident light on the center of the on-chip lens 140.

The prism-shaped on-chip lens 140 is able to increase a phase difference of the incident light inside and outside the on-chip lens 140 by increasing the height of the on-chip lens 14, and thus is able to curve the wave front of the incident light greatly to bend the incident light more strongly. Therefore, it is considered, as for the on-chip lens 140, that the change in the strength in bending the incident light depending on the height of the on-chip lens 140 also causes the focal distance of the on-chip lens 140 to vary. That is, the prism-shaped on-chip lens 140 is able to further shorten the focal distance by increasing the height of the on-chip lens 140, thus making it possible to achieve higher numerical aperture (Numerical Aperture: NA).

Accordingly, the prism-shaped on-chip lens 140, which has high numerical aperture, is thus able to further increase the maximum incident angle of the incident light on the scattering structure 121. In addition, the prism-shaped on-chip lens 140 is able to further reduce the diameter of an airy disc which is a spot size at the focal position. Therefore, it is also possible for the prism-shaped on-chip lens 140 to suppress a portion of the incident light condensed on a desired pixel being blocked by the light-blocking film 132 (i.e., occurrence of vignettings).

Next, specific description is given, with reference to FIG. 4, of diffraction by the scattering structure 121. FIG. 4 is an explanatory diagram that describes a condition of diffraction by the scattering structure 121.

The scattering structure 121, which is a cyclic uneven structure provided on the semiconductor substrate 100 on the light incident surface, functions as a diffraction grating in which scattering bodies are arranged cyclically. The diffraction grating is able to generate diffraction by causing the scattering body to interfere with and intensify scattered light.

Specifically, as illustrated in FIG. 4, light having entered at an incident angle α relative to a normal line of a grating plane of the diffraction grating in which scattering bodies 120 are arranged at a cycle w is scatted at each of the scattering bodies 120 and outputted at an output angle β relative to the normal line of the grating plane. At this time, on the side of the incident surface of the diffraction grating, light entering each of the scattering bodies 120 generates an optical path difference of w×sin α from light entering a neighboring scattering body 120. In addition, on an output surface side of the diffraction grating, light scattered by each of the scattering bodies 120 generates an optical path difference of w×sin β from light scattered by a neighboring scattering body 120.

Accordingly, in a case where a diffraction condition represented by the following Expression 1 is satisfied, the diffraction grating is able to generate diffraction and intensity diffracted light. In Expression 1, m is an order, λ is a wavelength of incident light in vacuo, and n is refractive index of a medium.

w(sin α±sin β)=mλ/n . . . Expression 1

Assuming that cycle w of the diffraction grating is 400 nm, the wavelength λ of the incident light is 940 nm, and the refractive index n of the medium (e.g., SiO₂) is 1.4, the above Expression 1 in the first order (m=1) has no solution at α≤43°. That is, in a case where the incident light has a long wavelength, the value on the right side of Expression 1 becomes greater, and thus, in order for Expression 1 to hold true, it is important that α or β on the left side of Expression 1 be greater. Therefore, as for long-wavelength incident light, it is important that the incident light enter the diffraction grating at a greater incident angle in order to satisfy the first-order diffraction condition.

In the photodetector 1 according to the present embodiment, the prism-shaped on-chip lens 140 is provided, that is able to bend the incident light L more strongly than a spherical-shaped on-chip lens having the same height. Therefore, it becomes easy for the photodetector 1 according to the present embodiment to satisfy the condition of the diffraction by the scattering structure 121 even for the long-wavelength incident light L.

This enables the scattering structure 121 to further increase the length of the optical path of the incident light in the photoelectric conversion section 101 by efficiently diffracting the incident light. Thus, the photodetector 1 according to the present embodiment is able to cause the photoelectric conversion section 101 to photoelectrically convert the incident light efficiently, thus making it possible to further enhance light absorption efficiency for the incident light L.

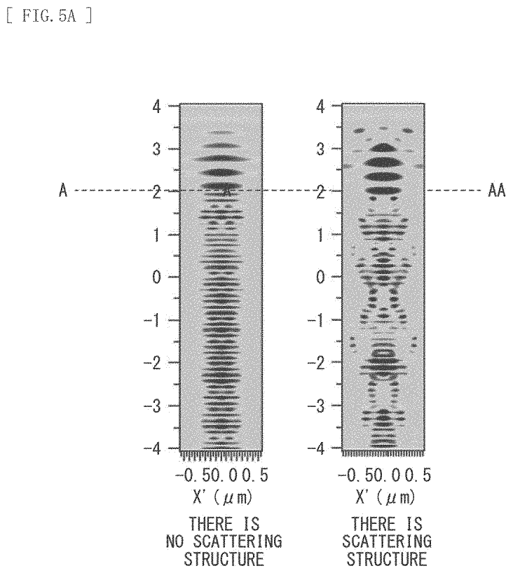

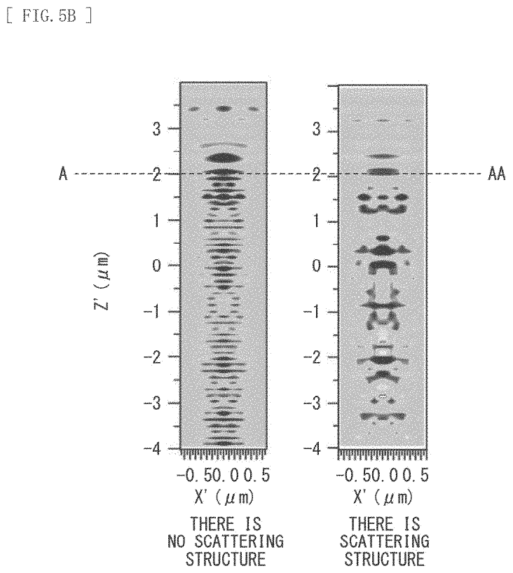

Next, description is given, with reference to FIGS. 5A and 5B, of results of confirmation, using simulations, of scattering of incident light in the photodetector according to the present embodiment. FIG. 5A is a heat map diagram estimating, using a 3D-FDTD method, a power distribution of the wave front of incident light in the photodetector including a spherical-shaped on-chip lens. FIG. 5B is a heat map diagram estimating, using the 3D-FDTD method, a power distribution of the wave front of incident light in the photodetector including a prism-shaped on-chip lens.

FIGS. 5A and 5B indicate that, as the brightness becomes lower, the power of the wave front basically becomes higher (i.e., light is condensed). In addition, FIGS. 5A and 5B each illustrate the power distribution of the wave front of the incident light in cross-section including the pixel center of the photodetector, and a line A-AA in FIGS. 5A and 5B corresponds to a lower surface of each on-chip lens.

As illustrated at the left of FIG. 5A, in a photodetector including a spherical-shaped on-chip lens but not including a scattering structure, the incident light includes a wave front shape with plane wave components remaining the most, and is in a state of being close to a parallel beam traveling straight in a thickness direction of the semiconductor substrate. In addition, as illustrated in the right of FIG. 5A, in a photodetector including a spherical-shaped on-chip lens and including a scattering structure, the incident light includes a wave front shape with plane wave components remaining, which however is a wave front shape also including an interference pattern with specific disturbance. Further, as illustrated in the left of FIG. 5B, in a photodetector including a prism-shaped on-chip lens but not including a scattering structure, the incident light has a wave front shape including an interference pattern with specific disturbance, similarly to that illustrated in the right of FIG. 5A.

Meanwhile, as illustrated in the right of FIG. 5B, the photodetector (corresponding to the photodetector according to the present embodiment) including the prism-shaped on-chip lens and including the scattering structure has a front shape including almost no plane wave, and has a wave front shape including the interference pattern with specific disturbance more strongly. That is, it is appreciated that, in the photodetector including the prism-shaped on-chip lens and including the scattering structure, diffraction by the scattering structure increases a component of the incident light traveling in an oblique direction, thus causing angular variance of the incident light to be increased. Such a photodetector is able to further increase the angular variance of the incident light, and thus it is expected that the length of the optical path of the incident light would be increased, allowing the light absorption efficiency for the incident light to be higher.

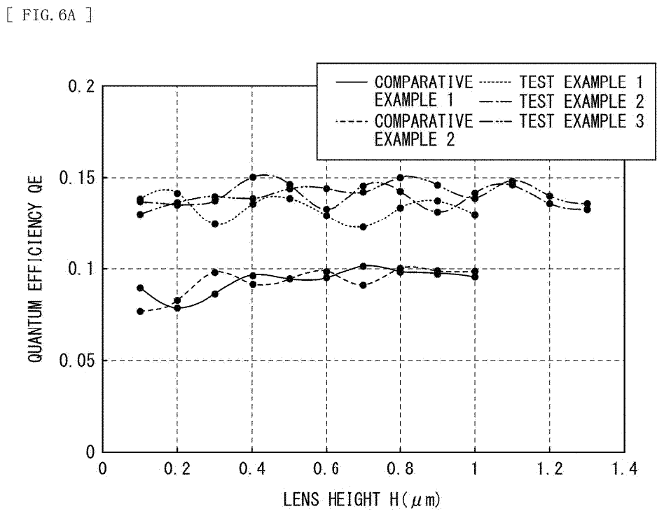

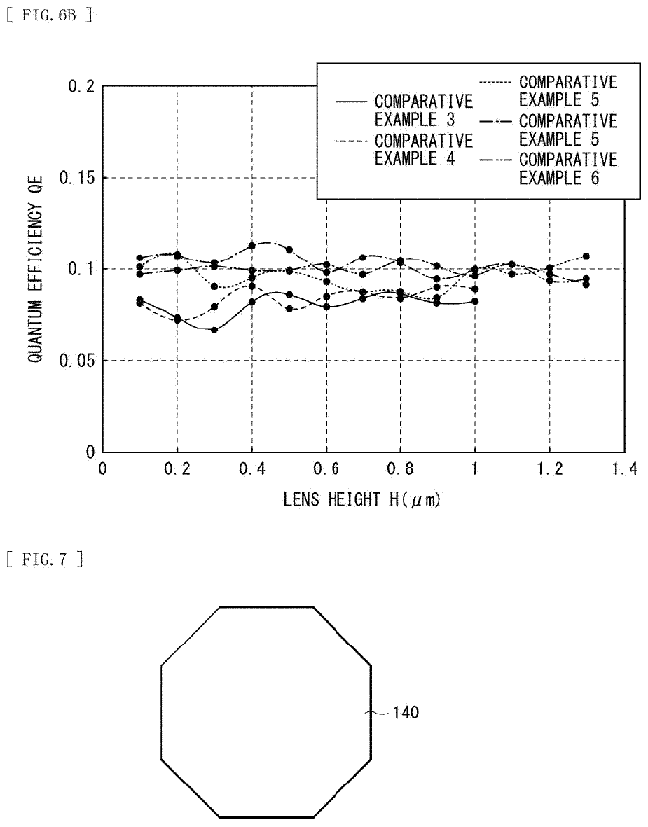

Next, description is given, with reference to FIGS. 6A and 6B, of results of confirmation, using simulations, of an improvement in the light absorption efficiency in the photodetector according to the present embodiment. FIG. 6A is a graph diagram estimating, using the 3D-FDTD method, quantum efficiency (light absorption efficiency) of the photodetector including a spherical-shaped or prism-shaped on-chip lens and including a scattering structure. FIG. 6B is a graph diagram estimating, using the 3D-FDTD method, quantum efficiency (light absorption efficiency) of the photodetector including a spherical-shaped or prism-shaped on-chip lens but not including a scattering structure. In FIGS. 6A and 6B, the quantum efficiency of the photodetector was estimated depending on the height of the on-chip lens.

In the simulations using the 3D-FDTD method, the pixel was shaped into a square of 1.5 μm on each side, and the width of the light-blocking film to be disposed on the boundary between pixels was set to 0.08 μm. In addition, the side surface of the photoelectric conversion section was set to be a condition for a cycle boundary, and the upper and lower surfaces of the photoelectric conversion section were set to be conditions for absorption of PML (Perfectly Matched Layer). Further, a near-infrared ray having a wavelength 940 nm was adopted as the incident light, and the structural cycle of the scattering structure was set to 400 nm.

Test Examples 1 to 3 in FIG. 6A each exhibit quantum efficiency in the photodetector including the scattering structure and the on-chip lens configured by prism-shaped Si₃N₄ having a square bottom surface of 1.3 μm on each side. In Test Examples 1 to 3, the thicknesses of the planarizing films differ from one another. In Test Example 1, the thickness of the planarizing film is 0.82 μm. In Test Example 2, the thickness of the planarizing film is 0.5 μm. In Test Example 3, the thickness of the planarizing film is 0.3 μm.

Comparative Examples 1 and 2 in FIG. 6A each exhibit quantum efficiency in the photodetector including the spherical-shaped on-chip lens and the scattering structure. In Comparative Examples 1 and 2, the materials of the spherical-shaped on-chip lenses differ from each other. In Comparative Example 1, the material of the on-chip lens is an organic resin. In Comparative Example 2, the material of the on-chip lens is Si₃N₄.

Comparative Examples 3 and 4 in FIG. 6B each exhibit quantum efficiency in the photodetector including the spherical-shaped on-chip lens but not including the scattering structure. In Comparative Examples 3 and 4, the materials of the spherical-shaped on-chip lenses differ from each other. In Comparative Example 3, the material of the on-chip lens is an organic resin. In Comparative Example 4, the material of the on-chip lens is Si₃N₄.

Comparative Examples 5 to 7 in FIG. 6B each exhibit quantum efficiency in the photodetector including the on-chip lens configured by prism-shaped Si₃N₄ having a square bottom surface of 1.3 μm on each side but not including the scattering structure. In Comparative Examples 5 to 7, the thicknesses of the planarizing films differ from one another. In Comparative Example 5, the thickness of the planarizing film is 0.82 μm. In Comparative Example 6, the thickness of the planarizing film is 0.5 μm. In Comparative Example 7, the thickness of the planarizing film is 0.3 μm.

As appreciated from Test Examples 1 to 3 and Comparative Examples 1 to 7 in FIGS. 6A and 6B, it is possible, in Test Examples 1 to 3 corresponding to the photodetector according to the present embodiment, to further improve the quantum efficiency, as compared with Comparative Examples 1 to 2, in which no prism-shaped on-chip lens is provided, and Comparative Examples 5 to 7, in which no scattering structure is provided. That is, the photodetector according to the present embodiment, which includes, in combination, the prism-shaped on-chip lens and the scattering structure, makes it possible to improve quantum efficiency particularly for long-wavelength incident light.

As appreciated from the above description, in the photodetector 1 according to the present embodiment, the prism-shaped on-chip lens 140 is able to further increase the maximum incident angle of the incident light L on the scattering structure 121, thus making it possible to cause the scattering structure 121 to generate diffracted light more efficiently. Therefore, in the photodetector 1 according to the present embodiment, it is possible to improve the light absorption efficiency for the incident light L in the photoelectric conversion section 101, thus making it possible to acquire an image with more favorable image quality.

Further, description is given, with reference to FIGS. 7 to 9, of a variation of the on-chip lens 140 included in the photodetector 1 according to the present embodiment. FIG. 7 is a top view of a variation of a planar configuration of the prism-shaped on-chip lens 140.

As described above with reference to FIG. 2B, the on-chip lens 140 may be provided, for example, to have a prismatic shape in which the bottom surface is quadrangular. In addition, as illustrated in FIG. 7, the on-chip lens 140 may be provided, for example, to have a prismatic shape in which the bottom surface is octagonal. The on-chip lens 140 includes a pair of bottom surfaces parallel to the light incident surface of the semiconductor substrate 100; the shape of the bottom surface is not particularly limited as long as the on-chip lens 140 has a prismatic shape extending in a direction perpendicular to the surface, of the semiconductor substrate 100, on the light incident side.

However, in order to further enhance the light absorption efficiency in the photoelectric conversion section 101, it is preferable that the shape of the bottom surface of the on-chip lens 140 be square.

For example, in a case where the on-chip lens 140 is formed using lithography, a corner of a polygonal shape of the bottom surface of the on-chip lens 140 may not possibly be formed precisely by diffraction during exposure. In such a case, the on-chip lens 140 may be formed in a prismatic shape having a bottom surface in a polygonal shape close to a circular shape. However, in the photodetector 1 according to the present embodiment, by providing the on-chip lens 140 in the prismatic shape having a bottom surface in a quadrangular shape close to the pixel shape, it is possible to further improve the light absorption efficiency in the photoelectric conversion section 101.

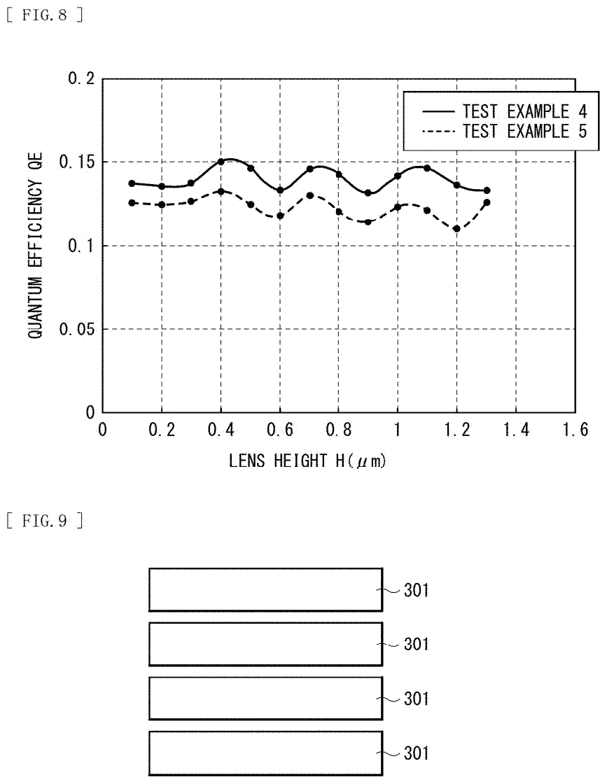

FIG. 8 illustrates results of estimation, using simulations, of light absorption efficiency of a photodetector including a quadrangular-prism-shaped on-chip lens and light absorption efficiency of a photodetector including an octagonal-prism-shaped on-chip lens. FIG. 8 is a graph diagram estimating, using the 3D-FDTD method, quantum efficiency (light absorption efficiency) of the photodetector including the quadrangular-prism-shaped or the octagonal-prism-shaped on-chip lens. In FIG. 8, the quantum efficiency of the photodetector was estimated depending on the height of the on-chip lens.

In the simulations using the 3D-FDTD method, the pixel was shaped into a square of 1.5 μm on each side, and the width of the light-blocking film to be disposed on the boundary between pixels was set to 0.08 μm. In addition, the side surface of the photoelectric conversion section was set to be a condition for a cycle boundary, and the upper and lower surfaces of the photoelectric conversion section were set to be conditions for absorption of PML (Perfectly Matched Layer). Further, a near-infrared ray having a wavelength 940 nm was adopted as the incident light, and the structural cycle of the scattering structure was set to 400 nm.

Test Example 4 in FIG. 8 exhibits quantum efficiency in a photodetector including a quadrangular-prism-shaped on-chip lens having a quadrangular bottom surface of 1.3 μm on each side. Test Example 5 exhibits quantum efficiency in a photodetector including an octagonal-prism-shaped on-chip lens having an octangular bottom surface with four corners being cut by 0.375 μm from the quadrangle of 1.3 μm on each side.

As appreciated from Test Examples 4 and 5 in FIG. 8, the photodetector including the quadrangular-prism-shaped on-chip lens (Test Example 4) has improved quantum efficiency as compared with the photodetector including the octagonal-prism-shaped on-chip lens (Test Example 5). Therefore, providing the photodetector with the prism-shaped on-chip lens having a quadrangular bottom surface close to the pixel shape makes it possible to further improve the light absorption efficiency in the photoelectric conversion section.

Such a quadrangular-prism-shaped on-chip lens 140 is able to be formed, for example, by performing exposure twice using a mask 301 extending in one direction as illustrated in FIG. 9 by rotating the mask 301 by 90 degrees. FIG. 9 is a plan view of an example of the mask 301 to be used for patterning of the quadrangular-prism-shaped on-chip lens 140.

Specifically, in lithography exposure, diffraction is likely to occur in a pattern such as a corner of a polygon due to an optical proximity effect, thus making it difficult to form a pattern faithful to the mask. Therefore, it is possible to form a resist patterned into a quadrangular shape by using the mask 301 extending in one direction not including the pattern such as the corner of the polygon to perform exposure twice in directions rotated by 90 degrees with each other. This enables formation of the quadrangular-prism-shaped on-chip lens 140 with higher precision. It is to be noted that the patterns of the line and the space in the mask 301 may be inverted depending on the characteristics of the resist.

### 3. MODIFICATION EXAMPLES

### 3.1. First Modification Example

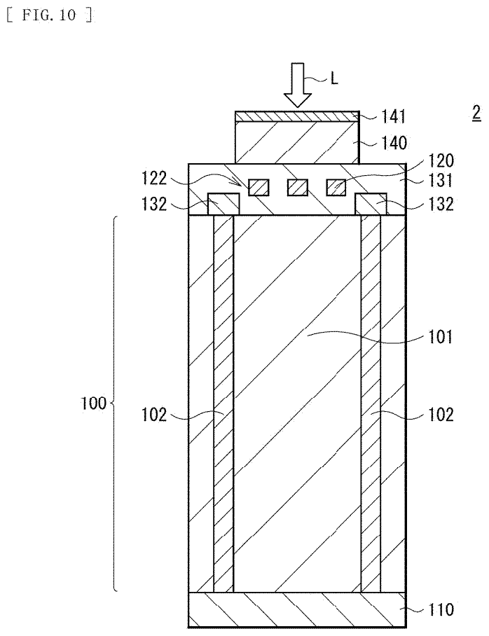

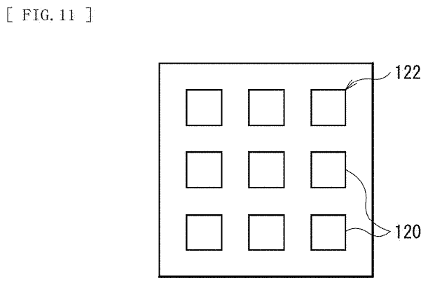

Next, description is given, with reference to FIGS. 10 and 11, of a photodetector according to a first modification example of the present embodiment. FIG. 10 is a longitudinal cross-sectional view of a cross-sectional configuration of a photodetector 2 according to the first modification example.

As illustrated in FIG. 10, the photodetector 2 includes, for example, the wiring layer 110, the semiconductor substrate 100 including the photoelectric conversion section 101 and the element separation section 102, a scattering structure 122, the light-blocking film 132, the planarizing film 131, the on-chip lens 140, and the antireflection film 141.

The photodetector 2 according to the first modification example differs from the photodetector 1 illustrated in FIG. 1 in that the scattering structure 122 is provided to have a diffraction grating structure in which a plurality of scattering bodies 120 are arranged cyclically. As for other configurations, descriptions thereof are omitted here, because the photodetector 2 according to the first modification example and the photodetector 1 illustrated in FIG. 1 are substantially similar.

The scattering structure 122 is a diffraction grating structure in which the scattering bodies 120 are cyclically provided inside the planarizing film 131. Similarly to the cyclic uneven structure formed on the semiconductor substrate 100, the scattering structure 122 is able to scatter or diffract the incident light L on the photodetector 2,.

The scattering body 120 is configured by a material different from that of the planarizing film 131 in the refractive index or absorptivity of light. For example, in a case where the planarizing film 131 is configured by an organic resin or the like, the scattering body 120 may be configured by Si₃N₄, poly-Si, microcrystalline Si, amorphous Si, TiO₂, Al, or the like.

Description is given of a specific structure of the scattering structure 122 with reference to FIG. 11. FIG. 11 is a top view of a planar configuration of the scattering structure 122 in FIG. 10.

As illustrated in FIGS. 10 and 11, the scattering structure 122 may be provided as a diffraction grating structure in which quadrangular-shaped scattering bodies 120 are arranged cyclically in each of two-dimensional directions in the plane of the semiconductor substrate 100. For example, in a case where the pixel has a square shape of 1.5 μm on each side, the scattering bodies 120 may be provided in a cycle of 400 nm. This allows the scattering structure 122 to be provided as the diffraction grating structure in which the scattering bodies 120 are arranged to be spaced apart from each other in a matrix of three rows and three columns within the pixel.

According to the photodetector 2 according to the first modification example, it is possible to cause the scattering structure 122 to efficiently diffract light entering the photoelectric conversion section 101, similarly to the photodetector 1 illustrated in FIG. 1. Thus, the photodetector 2 according to the first modification example is able to cause the photoelectric conversion section 101 to photoelectrically convert the incident light efficiently, thus making it possible to further enhance the light absorption efficiency for the incident light L.

However, the scattering structure 122 is not limited to the diffraction grating structure exemplified above. The scattering structure 122 may be a diffraction grating structure in which longitudinal-shaped scattering bodies 120 are arranged cyclically in one direction as long as the diffraction grating structure is able to generate diffraction for the incident light L.

### 3.2. Second Modification Example

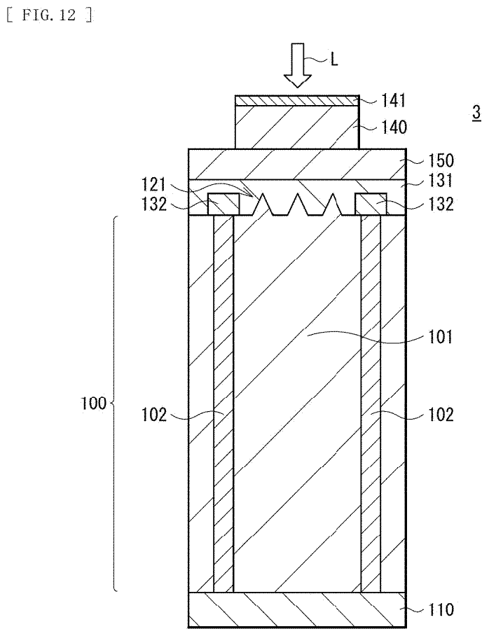

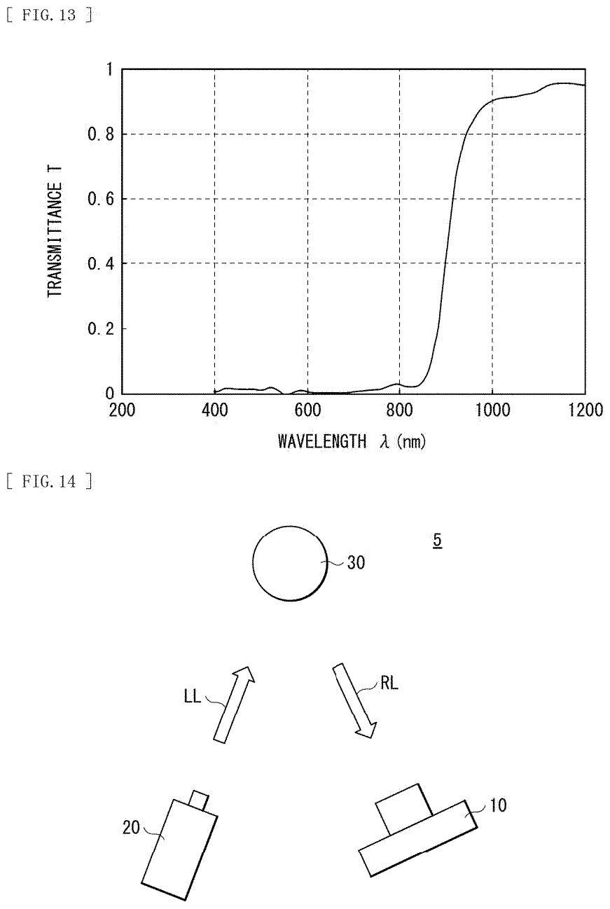

Next, description is given of a photodetector according to a second modification example of the present embodiment with reference to FIGS. 12 and 13. FIG. 12 is a longitudinal cross-sectional view of a cross-sectional configuration of a photodetector 3 according to the second modification example.

As illustrated in FIG. 12, the photodetector 3 includes, for example, the wiring layer 110, the semiconductor substrate 100 including the photoelectric conversion section 101 and the element separation section 102, the scattering structure 121, the light-blocking film 132, the planarizing film 131, an infrared filter 150, the on-chip lens 140, and the antireflection film 141.

The photodetector 3 according to the second modification example differs from the photodetector 1 illustrated in FIG. 1 in that the infrared filter 150 is provided. As for other configurations, descriptions thereof are omitted here, because the photodetector 3 according to the second modification example and the photodetector 1 illustrated in FIG. 1 are substantially similar.

It is to be noted that the photodetector 3 according to the second modification example may include the scattering structure 122 that is the diffraction grating structure in which the plurality of scattering bodies 120 are arranged cyclically, instead of the scattering structure 121 that is the cyclic uneven structure formed on the semiconductor substrate 100.

The infrared filter 150 is an optical filter that absorbs a visible light ray and transmits a near-infrared ray (e.g., light having a wavelength of 700 nm to 2500 nm). For example, the infrared filter 150 may be an optical filter having a light transmittance spectrum illustrated in FIG. 13. FIG. 13 is a graph diagram illustrating an example of a light transmittance spectrum of the infrared filter 150. According to the optical filter having the light transmittance spectrum illustrated in FIG. 13, it is possible to selectively transmit a near-infrared ray having a wavelength of 850 nm or more.

Accordingly, the photodetector 3 provided with the infrared filter 150, which selectively transmits a near-infrared ray, between the on-chip lens 140 and the planarizing film 131 makes it possible to suppress incidence of a visible light ray on the scattering structure 121. Therefore, the photodetector 3 is able to reduce noises included in results of detection of a near-infrared ray in a case of detection of the near-infrared ray. Therefore, the photodetector 3 according to the second modification example is able to reduce noises when detecting the near-infrared ray (e.g., light having a wavelength of 700 nm to 2500 nm), thus making it possible to acquire a near-infrared image with favorable image quality.

### 4. APPLICATION EXAMPLE

Here, description is given of an application example of the photodetector 1 according to the present embodiment with reference to FIG. 14. FIG. 14 is an explanatory diagram illustrating an overview of a camera system 5 including the photodetector 1 according to the present embodiment.

As illustrated in FIG. 14, the camera system 5 includes, for example, a light source 20 and an imaging device 10. The light source 20 is, for example, a semiconductor laser that irradiates a subject 30 with irradiation light LL of a near-infrared ray (in particular, light having a wavelength of 940 nm). The light source 20 may be, for example, an AlGaAs-based semiconductor laser. The light source 20, which is configured by a semiconductive laser, is able to irradiate the subject 30 efficiently with highly directional light. The imaging device 10 is an imaging device that includes the photodetector 1 according to the present embodiment and detects reflected light RL from the subject 30 irradiated with the irradiation light LL.

This enables the camera system 5 to perform, by means of ToF (Time of Flight) or pattern projection (Structured light), for example, distance measurement with respect to the subject 30 or shape recognition of the subject 30.

Specifically, in a case of being used for the ToF, the camera system 5 first irradiates the subject 30 with the irradiation light LL from the light source 20. Next, the camera system 5 measures time until the imaging device 10 detects the reflected light RL from the subject 30 irradiated with the irradiation light LL. This enables the camera system 5 to calculate the distance to the subject 30 by means of iToF (Indirect ToF) or dToF (Direct ToF).

According to the iToF, the camera system 5 is able to calculate the distance to the subject 30 from a signal intensity ratio (phase difference) by reading two or more divided signals in one pixel with a time difference. In addition, according to the dToF, the camera system 5 is able to calculate the distance to the subject 30 from a difference in time until the irradiation light LL is reflected by the subject 30 and returned as the reflected light RL.

In a case of being used for the pattern projection (Structured light), the camera system 5 first irradiates the subject 30 with the irradiation light LL including a pattern from the light source 20. Next, the camera system 5 causes the imaging device 10 to detect a pattern included in the reflected light RL reflected from the subject 30 irradiated with the irradiation light LL. This enables the camera system 5 to calculate, from a deviation between the pattern in the irradiation light LL and the pattern in the reflected light RL, the distance to the subject 30 or the shape of the subject 30.

The description has been given hereinabove of the technology according to the present disclosure with reference to the embodiment and the modification examples. The technology according to the present disclosure is not, however, limited to the embodiments or the like described above, and may be modified in a wide variety of ways.

Further, not all of the components and operations described in the respective embodiments are necessary as the components and operations according to the present disclosure. For example, among components according to the respective embodiments, a component that is not described in an independent claim reciting the most generic concept of the present disclosure should be understood as an optional component.

Terms used throughout this specification and the appended claims should be construed as “non-limiting” terms. For example, the term “including” or “included” should be construed as “not limited to what is described as being included”. The term “having” should be construed as “not limited to what is described as being had”.

The terms used herein are used merely for the convenience of description and include terms that are not used to limit the configuration and the operation. For example, the terms such as “right”, “left”, “up”, and “down” only indicate directions in the drawings being referred to. In addition, the terms “inside” and “outside” only indicate a direction toward the center of a component of interest and a direction away from the center of a component of interest, respectively. The same applies to terms similar to these and to terms with the similar purpose.

It is to be noted that the technology according to the present disclosure may also have the following configurations. According to the technology of the present disclosure having the following configurations, the photodetector is able to cause the prism-shaped on-chip lens to further increase the maximum incident angle of incident light entering the scattering structure, thus enabling the scattering structure to generate diffraction of the incident light more strongly. Therefore, it is possible to for the photodetector to further increase the length of the optical path of the incident light in the photoelectric conversion section by the diffraction of the incident light, thus enabling the photoelectric conversion section to absorb the incident light more efficiently. Thus, it is possible for the photodetector to further improve the light absorption efficiency for the incident light. Effects achieved by the technology according to the present disclosure are not necessarily limited to the effects described herein, but may include any of the effects described in the present disclosure.

(1)

A photodetector including:
a semiconductor substrate including therein a photoelectric conversion section;
a scattering structure provided cyclically on the semiconductor substrate on a side of an incident surface of light; and
a prism-shaped on-chip lens provided further on the scattering structure on a side of an incident surface of the light, the prism-shaped on-chip lens having a planar incident surface of the light.
   (2)

The photodetector according to (1), in which the scattering structure includes a cyclic uneven structure formed on the semiconductor substrate.

(3)

The photodetector according to (2), in which a recess of the uneven structure has a quadrangular pyramid shape or a truncated quadrangular pyramid shape.

(4)

The photodetector according to (1), in which the scattering structure includes a diffraction grating structure in which a plurality of scattering bodies are arranged cyclically.

(5)

The photodetector according to (4), in which
the diffraction grating structure is provided inside a planarizing film between the semiconductor substrate and the on-chip lens, and
the scattering body includes a material that is different from the planarizing film in a refractive index of the light or in an absorptivity of the light.
   (6)

The photodetector according to any one of (1) to (5), in which the scattering structure has a structural cycle that satisfies a condition of diffraction for a wavelength of the light.

(7)

The photodetector according to any one of (1) to (6), in which the light includes a near-infrared ray.

(8)

The photodetector according to any one of (1) to (7), in which the scattering structure is provided cyclically in each of two-dimensional directions inside a plane of the semiconductor substrate.

(9)

The photodetector according to any one of (1) to (8), in which the on-chip lens has a quadrangular prism shape.

(10)

The photodetector according to any one of (1) to (9), in which the semiconductor substrate includes an element separation section extending in a thickness direction of the semiconductor substrate, the element separation section separating an inside of the plane of the semiconductor substrate for each pixel.

(11)

The photodetector according to (10), in which the element separation section includes a material having a smaller refractive index than the semiconductor substrate.

(12)

A camera system including a photodetector,
the photodetector including
   a semiconductor substrate including therein a photoelectric conversion section,
   a scattering structure provided cyclically on the semiconductor substrate on a side of an incident surface of light, and
   a prism-shaped on-chip lens provided further on the scattering structure on a side of an incident surface of the light, the prism-shaped on-chip lens having a planar incident surface of the light.
      (13)

The camera system according to (12), further including a light source that irradiates a subject with laser light, in which
the photodetector detects reflected light of the laser light from the subject.

This application claims the benefit of Japanese Priority Patent Application JP2020-124037 filed with the Japan Patent Office on Jul. 20, 2020, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A photodetector comprising:
a semiconductor substrate including therein a photoelectric conversion section;
a scattering structure provided cyclically on the semiconductor substrate on a side of an incident surface of light; and
a prism-shaped on-chip lens provided further on the scattering structure on a side of an incident surface of the light, the prism-shaped on-chip lens having a planar incident surface of the light.

2. The photodetector according to claim 1, wherein the scattering structure comprises a cyclic uneven structure formed on the semiconductor substrate.

3. The photodetector according to claim 2, wherein a recess of the uneven structure has a quadrangular pyramid shape or a truncated quadrangular pyramid shape.

4. The photodetector according to claim 1, wherein the scattering structure comprises a diffraction grating structure in which a plurality of scattering bodies are arranged cyclically.

5. The photodetector according to claim 4, wherein
the diffraction grating structure is provided inside a planarizing film between the semiconductor substrate and the on-chip lens, and
the scattering body includes a material that is different from the planarizing film in a refractive index of the light or in an absorptivity of the light.

6. The photodetector according to claim 1, wherein the scattering structure has a structural cycle that satisfies a condition of diffraction for a wavelength of the light.

7. The photodetector according to claim 1, wherein the light comprises a near-infrared ray.

8. The photodetector according to claim 1, wherein the scattering structure is provided cyclically in each of two-dimensional directions inside a plane of the semiconductor substrate.

9. The photodetector according to claim 1, wherein the on-chip lens has a quadrangular prism shape.

10. The photodetector according to claim 1, wherein the semiconductor substrate includes an element separation section extending in a thickness direction of the semiconductor substrate, the element separation section separating an inside of a plane of the semiconductor substrate for each pixel.

11. The photodetector according to claim 10, wherein the element separation section includes a material having a smaller refractive index than the semiconductor substrate.

12. A camera system comprising a photodetector,
the photodetector including
a semiconductor substrate including therein a photoelectric conversion section,
a scattering structure provided cyclically on the semiconductor substrate on a side of an incident surface of light, and
a prism-shaped on-chip lens provided further on the scattering structure on a side of an incident surface of the light, the prism-shaped on-chip lens having a planar incident surface of the light.

13. The camera system according to claim 12, further comprising a light source that irradiates a subject with laser light, wherein
the photodetector detects reflected light of the laser light from the subject.
